(19) United States
(12) Patent Application Publication
(10) Pub. No.: US 2023/0345884 A1
(43) Pub. Date: Nov. 2, 2023

(54) GROUND COVER MATERIALS

(71) Applicant: NINE IP LIMITED, Auckland (NZ)

(72) Inventor: Jonathan Dallas TOYE, Bangkok (TH)

(21) Appl. No.: 18/021,379

(22) PCT Filed: Aug. 9, 2021
(86) PCT No.: PCT/IB2021/057309

§ 371 Date: Feb. 14, 2023

(30) Foreign Application Priority Data
Aug. 14, 2020 (NZ) 767067

(51) Int. Cl. C08K 3/22; A01G 13/02; G02B 26/08

(52) U.S. Cl. CPC A01G 13/0275; C08K 3/22; G02B 26/0816; C08K 2003/2241

(57) ABSTRACT

A ground cover material for use in horticulture has on one side a low white layer comprising a transparent or translucent polymer and a low amount of a white pigment or pigments, and on an opposite side a metallized layer. In use the material is placed beneath fruit trees for example, and provides a balance of direct and diffuse reflection of incident solar radiation back to the fruit trees.

### TECHNICAL FIELD

The disclosure relates to ground cover metallized plastic film sheet materials and to ground cover sheets comprising such materials.

### BACKGROUND

Typically white ground film cover sheet materials are rolled out in lengths onto the ground, and secured in place, beneath or between rows of trees, vines, or other plants, to increase the amount of light to which the plants and in particular fruit are exposed. White reflective ground cover materials or aluminium reflective ground cover materials may be used in an orchard or vineyard for example, to increase reflected light into the plant canopy, to enhance ripening of fruit including but not limited to colouring of the fruit, before picking or harvesting the fruit.

Most white reflective film ground cover materials are produced by adding a white pigment of a type and in an amount that will give the desired reflective properties e.g. Titanium dioxide, to a base polymer and then extruding as a film. White ground covers reflect diffuse light and reflect a narrower spectrum than aluminium reflectors. White films are more expensive to make then clear films metalized with aluminium due to the differences in their manufacturing process and materials used to achieve the needed reflectivity.

Aluminium reflective film ground cover materials comprise an aluminium layer metalized onto a clear, non-pigmented polymer base film. Aluminium reflective films reflect light directly not diffusely, in a mirror-like way, and are very effective high reflectivity solar reflectors and can be lower cost to make then white pigmented films. Aluminium reflective films reflect all wavelengths of the solar spectrum, and some aluminium reflective ground cover materials can be so reflective that, at least some locations, they provide excessive reflection leading to fruit ‘burning’ and as direct light reflector the light distribution is overly concentrated in locations in the plant canopy and not in other parts of the canopy or the whole fruit surface. While white films that are diffuse light reflectors giving a more even distribution of light and reflect a narrower solar radiation spectrum that supports less fruit burning, white materials are more expensive.

### SUMMARY OF DISCLOSURE

It is an object of the present disclosure to provide improved metallized reflective film ground cover materials, or to at least provide the public with a useful choice.

In broad terms in a first aspect the disclosure comprises a ground cover sheet material having a greater length than width and comprising:
one side comprising a light energy altering and/or diffusing and/or absorbing white or coloured layer or layers comprising or composed of a transparent or translucent polymer or polymers and a low amount of a white pigment and/or coloured pigment or pigments or coloured dye or coloured dyes such that the side is white-translucent or low coloured-translucent, and
the other side comprising a metallized layer.

In use the material is placed on the ground beneath or between rows of trees, vines, or other plants, with the low white-translucent or low coloured-translucent side up and the metallized side down. The low white-translucent side, or low coloured-translucent side, consisting of a clear or translucent polymer or polymers containing a low amount of a white or coloured pigment or coloured dye, is white-translucent or low coloured-translucent (not opaque). This layer acts as an energy absorber and/or diffuser for both incident solar radiation light and light reflected from the metallized layer. As incident solar radiation passes though the white-translucent or low coloured-translucent layer to the metallized layer, a proportion of the light is diffused or absorbed or altered. On striking the metallized layer, all wavelengths of the solar spectrum are reflected and pass through the white-translucent or low coloured-translucent layer again, allowing for additional light diffusion or absorption or the light wave energy to be altered. Such a process provides an efficient method to increase the portion of diffuse or altered energy light to the direct light. This change in the balance of diffuse and direct light and the change in wavelength energy allows enhancement of plant response along with reduced sunburn that can come from direct light, while providing enhanced light penetration into the plant canopy due to increased light diffusion, improving fruit qualities such as colour development over a greater proportion of the fruit surface.

In some embodiments the ground cover sheet material is in the form of a film which is between 1 and 50, 5 and 45, 10 and 40, or 14 and 35 microns thick.

In another aspect the present disclosure provides a ground cover sheet material of any of the above embodiments in the form of a tape or film which is between 10 and 150, 10 and 100, 20 and 90, 30 and 80, 35 and 60, 35 and 55, or 40 and 60 microns thick.

In some embodiments the low white-translucent or low coloured-translucent layer, or layers, may also absorb solar certain wavelengths that can lead to fruit burn or wavelengths that are less favourable to fruit development and/or colour development on the fruit surface.

In some embodiments the low white-translucent or low coloured-translucent layer can also comprise one or more pigments or dyes which absorb and/or diffuse infrared and/or UV wavelengths. In particular the low white-translucent or low coloured-translucent layer can also comprise one or more pigments or dyes which absorb and/or diffuse infrared and/or UV wavelengths to a greater extent than visible wavelengths are absorbed and/or diffused. This may reduce the amount of infrared and/or UV light reaching the aluminium layer and/or increase the proportion of reflected diffuse infrared and/or UV light and reduce the proportion of reflected direct infrared and/or UV light. This may reduce or avoid localised and concentrated heat and/or UV spots in the plant canopy and reduce fruit burn risk.

Diffuse infrared and/or UV light has a reduced ability to cause heat spots in the plant canopy and reduced fruit burn risk.

In some embodiments the non-metallized side can also comprise one or more layers which absorb and/or diffuse infrared and/or UV wavelengths. In particular, one discreet low white-translucent or low coloured-translucent layer can comprise one or more pigments or dyes which absorb and/or diffuse infrared and/or UV wavelengths to a greater extent than visible wavelengths are absorbed and/or diffused. Another discreet layer or layers can comprise one or more pigments or dyes which are different to the other discreet layer and which absorb and/or diffuse infrared and/or UV wavelengths to a greater extent than visible wavelengths are absorbed and/or diffused. This may reduce the amount of infrared and/or UV light reaching the aluminium layer and/or increase the proportion of reflected diffuse infrared and/or UV light and reduce the proportion of reflected direct infrared and/or UV light. This may reduce or avoid localised and concentrated heat and/or UV spots in the plant canopy and reduce fruit burn risk. Diffuse infrared and/or UV light has a reduced ability to cause heat spots in the plant canopy and reduced fruit burn risk.

In any embodiment above the low white-translucent or low coloured-translucent layer or layers can also comprise one or more non-white, coloured pigments or dyes. In particular the low white-translucent or low coloured-translucent layer or layers, can also comprise one or more non-white coloured pigments or dyes which affect the visible spectrum by altering the balance between different wavelengths of the visible light spectrum.

Alternatively the low white-translucent or low coloured-translucent layer or layers, may contain one or more, non-white coloured pigments or dyes that reflect more diffuse light than direct light and wherein the reflected light expresses the colour of the pigment or dye. Alternatively the low white-translucent or low coloured-translucent layer, or layers, may contain a non-white coloured pigment or dye that reflects more diffuse light than direct light and reduce the proportion of reflected UV or infrared light compared to the visible wavelengths.

The material of the disclosure may be better than an aluminium reflective ground cover material (aluminium and clear polymer only) because it may reflect less direct light, including IR and UV wavelengths, to the trees, vines, or other plants, thus reducing the likelihood of sunburn of fruit (fruit burn), plant light-stress or phototoxicity. It may also reflect more light across the visible wavelengths, compared to clear polymer and aluminium, to improve plant response. The light reflected by the material to the trees, vines, or other plants is a mixture of direct reflected and diffuse reflected light, instead of all direct reflected light. This combination gives an improved light distribution throughout the plant canopy near the film. This improved light distribution can improve the fruit quality, including colour development.

Also, the amounts and ratios of direct reflected and diffuse reflected light and/or the amount of reflected IR and/or UV and/or visible wavelengths, or of direct reflected and diffuse reflected IR and/or UV and/or visible wavelengths, can be varied for different embodiments of the material of the disclosure, by varying the amount or type of the white pigment, and/or infrared or UV absorbing pigments, and/or infrared or UV diffusing pigments and/or non-white coloured pigment or dye, in the low white- or low-coloured translucent layer or layers.

The amounts and ratios of direct reflected and diffuse reflected light can be varied in different embodiments of the material, for different fruit or plant types and/or different environments i.e. different for high sunshine hours vs lower sunshine hours environments, different latitudes, specific fruit varieties and different times of the growing season e.g. spring, summer and autumn or early harvest, mid harvest, or late harvest.

In broad terms in a second aspect the disclosure comprises a method for enhancing the growth or development of fruit comprising providing beneath fruit bearing plants a ground cover sheet material as described above, with the reflective white pigmented, or coloured transparent or translucent polymer layer uppermost in combination with a metallized layer.

### Definitions

By ‘directly reflective’ or ‘specular reflective’ is meant that reflected light is reflected at the same angle to the reflecting surface as the incident light, but on the opposing side of the surface normal in the plane formed by incident and reflected rays, providing mirror-like reflection.

By ‘diffusely or diffuse reflective’ or ‘reflects light diffusely or diffused’ is meant that incident light is reflected at many different angles to the reflecting surface as the incident light, rather than at just one angle as in specular reflection.

By ‘reflective’ in general is meant that the material is reflective of at least 50% of visible light on at least one side of the material. Typically this refers to reflectance from the material to the trees.

By ‘UV’ is meant the Ultra-Violet wavelength range of about 280-400 nm.

By ‘visible’ is meant the wavelength range of about 400-700 nm.

By ‘NIR’ is meant at least the near infrared wavelength range of about 700-800 nm. By ‘IR’ is meant the Infrared spectrum from 700 nm to 2,500 nm.

As used herein the term ‘and/or’ means ‘and’ or ‘or’, or both.

As used herein ‘(s)’ following a noun means the plural and/or singular forms of the noun.

It is intended that reference to a range of numbers disclosed herein (for example, 1 to 10) also incorporates reference to all rational numbers within that range (for example, 1, 1.1, 2, 3, 3.9, 4, 5, 6, 6.5, 7, 8, 9 and 10) and also any range of rational numbers within that range (for example, 2 to 8, 1.5 to 5.5 and 3.1 to 4.7) and, therefore, all sub-ranges of all ranges expressly disclosed herein are hereby expressly disclosed. These are only examples of what is specifically intended and all possible combinations of numerical values between the lowest value and the highest value enumerated are to be considered to be expressly stated in this application in a similar manner.

### Measurement of Optical Properties

In this specification, diffuse reflectance and transmittance data has been measured according to the method of measurement described below using a Thermofisher Nicolet 8700 FTIR spectrometer and/or with a Smart Diffuse Reflectance accessory and/or UV-Vis Shimadzu UV-2700 spectrometer. The FTIR light source is a current regulated tungsten halogen lamp. The measurement angle is 45-degrees. The beam passes through a quartz prism and is then detected on the opposite side from the beam source. Potassium bromide (KBr) is used as a white reflectance reference material. The detector is usually a silicon photodiode. The system is controlled using OMNIC software and/or:

A spectrophotometer system based around a GSA/McPherson 2051 1 metre focal length monochromator fitted with a prism predisperser and also stray light filters. The light source is a current regulated tungsten halogen lamp. The bandwidth is adjustable up to 3 nm. The monochromatic beam from the monochromator is focused onto the sample or into the integrating sphere using off-axis parabolic mirrors. The integrating spheres are coated with pressed halon powder (PTFE powder). Halon powder is also used as a white reflectance reference material. The detector is usually a silicon photodiode connected to an electrometer amplifier and digital volt meter. The whole system is controlled using software written in LabVIEW. The detectors used can be photomultiplier tubes, silicon diodes or lead sulphide detectors.

### Diffuse Reflectance Sphere

The diffuse reflectance was measured using an integrating sphere with an internal diameter of 75 mm with the sample tilted at an angle of 6° to the incident light (specular reflectance included). The reference sample is pressed halon powder and a black cone is used to correct for stray light. Up to four test samples are mounted on a pneumatic driven sample changer along with the white reference and black cone.

### Diffuse Transmittance Sphere

The diffuse transmittance was measured using an integrating sphere with an internal diameter of 120 mm and coated with pressed halon powder. The sample is mounted on one port and the incident light port is at an angle of 90° around the sphere. The sphere rotates by 90° in the horizontal plane to allow the focused incident light to enter the sphere through the incident light port or the incident light to be transmitted through the sample and enter the sphere. The detector is mounted at the top of the sphere.

### Absorbance

Absorbance is calculated as a back calculation from the calculated transmittance and reflectance values.

### Direct Reflectance Sphere

The direct reflectance was measured using an integrating sphere with the sample tilted at an angle of 6′ to the incident light. Monochromatic light is passed through the sphere entrance port and strikes a sample on the sample port. Direct and diffuse light are reflected back within the sphere. Using a calibrated reflectance standard with known reflectance value, the ratio between the signal measured with the reference standard in place and that of the test sample in place were used to calculate the reflectance of the test samples.

### BRIEF DESCRIPTION OF THE DRAWINGS

The disclosure is further described by way of example with reference to the accompanying drawings in which:

FIG. 1 shows ground cover sheet material of the disclosure anchored underneath rows of orchard trees to reflect solar radiation onto the fruit trees and fruit from below;

FIG. 2A is a cross-section view of a portion of a prior art ground cover material, comprising a single translucent non-pigmented polymer layer bonded to a layer of aluminum;

FIGS. 2B-2D are cross-section views of portions of embodiments of ground cover materials of the disclosure;

FIGS. 3A-J are cross-section views of a portion of the ground cover material of FIGS. 2B-2D schematically showing light reflection diffusion within the material in use; and

FIGS. 4A-4F show ground cover sheet material of the disclosure anchored underneath rows of orchard trees to reflect solar radiation onto the fruit trees and fruit from below, showing direct and diffuse reflection from the material when the sun is at different angles during the day.

### DETAILED DESCRIPTION

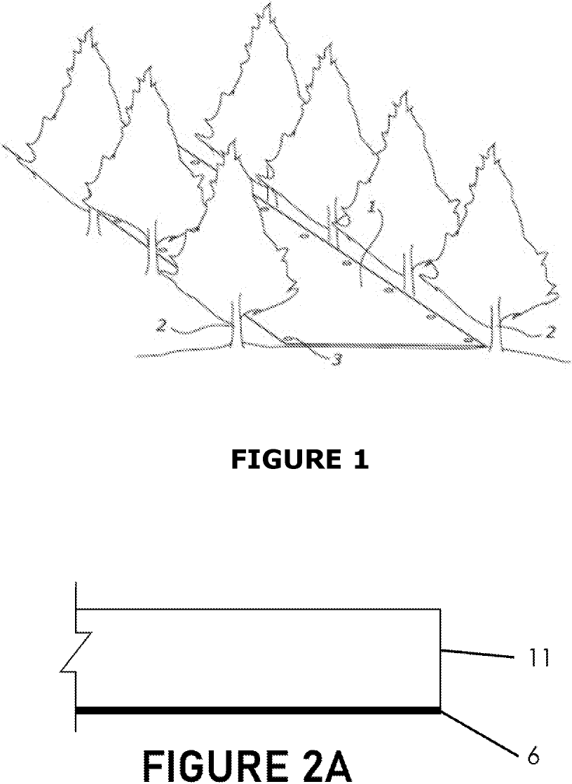

Referring to FIG. 1, ground cover sheet material 1 is anchored underneath agricultural crops such as rows of orchard trees 2 to reflect solar radiation onto the fruit trees and fruit from below. In FIG. 1 only part of the length of sheeting is shown. Typically, long sections of the sheet material are anchored along both edges between rows of orchard trees or vines. For example, pins 3 are pushed though material along its edges and the pin point is pushed into the ground. Alternatively, soil may be placed on top of the material at the edges of the material to hold the material in place.

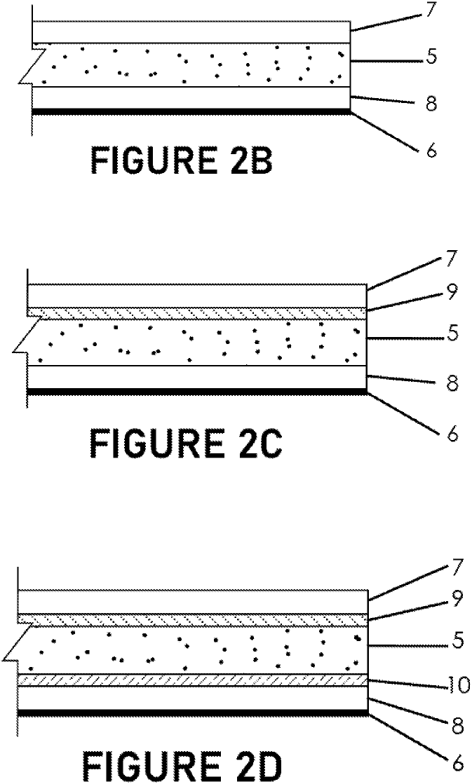

FIG. 2A is a cross-section view of a portion of a prior art ground cover material, comprising a single translucent non-pigmented polymer layer 11 and a bonded a layer of aluminum 6.

FIG. 2B is a cross-section view of a portion of an embodiment of a ground cover material of the disclosure . Referring to FIG. 2B, in this embodiment the material comprises one side a low white-translucent layer 5, or a low-colour pigment or dye layer 5, or a low white pigment and low-colour pigment or dye layer 5, and on the other side (underneath in use) a metallized layer 6.

In at least some embodiments the low white-translucent layer 5, or the metallized layer 6, or both, may be covered with a clear protective coating 7, or a layer comprising anti-block particles to aid rolling and unrolling of the film, or both.

Optionally a clear layer 8 may be present between the white pigmented layer 5 and the metallized layer 6 to increase adhesion between the layers.

FIGS. 2C-D are cross-section views of two further embodiments of ground cover materials of the disclosure . Referring to FIGS. 2C-2D, layers 5-8 are as before except that layer 5 is a low-white layer or a low-colour pigment or dye layer, or both, and in these embodiments there are additional layers 9 and/or 10 on the outer and inner sides of layer 5 respectively. Layers 9 and 10 comprise low-white or low-colour pigment or dye.

### Low White-Translucent or Low Coloured-Translucent Layer

As stated the low white-translucent layer comprises or is composed of a transparent or translucent polymer and a low amount of a white pigment (or a combination of pigments) such that the low white layer is white-translucent.

In another embodiment, the translucent layer comprises or is composed of a transparent or translucent polymer and a low amount of a white pigment and a low amount of colour pigments and/or dyes such that the layer is a low-white or low-coloured translucent layer.

In another embodiment, the translucent layer comprises or is composed of a transparent or translucent polymer and a low amount of colour pigments and/or dyes such that the layer is a low coloured-translucent layer.

In some embodiments the low coloured-translucent layer is translucent violet, indigo, blue, green, yellow, orange, red, grey, or black or a mixture of shades or colours.

In another embodiment, more than one layer is translucent. The translucent layers comprise or are composed of a transparent or translucent polymer and a low amount of colour pigments and/or dyes such that the layers are low-colour-translucent layers.

In another embodiment, more than one layer is translucent. The translucent layers comprise or are composed of a transparent or translucent polymer and a low amount of colour pigments and/or dyes such that the layers are low-colour-translucent layers and each low colour translucent layer comprises or is composed of a different colour pigment and/or dye to the other layers.

In some embodiments the low white layer or the low coloured-translucent layer comprises from 0.001% up to 40% by weight of a white pigment to the white layer itself or coloured pigment/dye to the low-coloured translucent layer or all layers of the film in total. The level of white or coloured pigments and/or dyes required may be influenced by the light refractive index of the particular chosen pigments or dyes. High refractive index pigments will be required in smaller amounts relative lower refractive index pigments.

In some embodiments the low white or low coloured layer comprises a white or coloured pigment or pigments or dyes in an amount up to 40% or 30% or 20% by weight of the low white or coloured layer, or in an amount up to 20% or 15%, 10%, 5%, 1%, 0.1%, 0.01% or 0.001% by weight of the whole material.

In some embodiments the low white or low coloured layer comprises pigment or pigments and/or dyes in an amount not more than 20%, 15%, 10%, 5%, 4%, 2%, 1%, 0.5%, 0.1%, 0.01% or 0.001% by weight of the low white or coloured layer, or in an amount not more than 20%, 15%, 10%, 5%, 4%, 2%, 1%, 0.5%, 0.1%, or 0.01% or 0.001% by weight of the whole material.

In some embodiments the white pigment comprises one or more pigments chosen from but not limited to the group consisting of titanium, titanate, zirconium, silica, strontium, zinc, barium, potassium, calcium, magnesium and sodium.

In some embodiments the white pigment comprises one or more metal oxide compounds comprising elements chosen from but not limited to the group consisting of titanium, titanate, zirconium, silica, strontium, zinc, barium, potassium, calcium, magnesium and sodium.

In some embodiments the low-coloured pigment or dye comprises, but is not limited to, the group of compounds comprising quinizarine, anthraquinone, diazo, anthracenedione, fluorophores, fluorochromes, fluorescein, Rhodamine, Neocarmine, Solvaperm Black PCR, benzotriazole, benzophenone, triazine, oxalanilide or a combination of low-colour and white pigment.

The amount of the white pigment is typically lower than the amount of the same white pigment that would be present in a material having similar optical properties, and using the same white pigment but not also comprising the metallized layer.

The amount of the coloured pigment or dye is typically lower than the amount of the same white pigment that would be present in a material having similar optical properties, and using the same white pigment but not also comprising the metallized layer.

In some embodiments the white pigment or coloured pigment or dye has an average particle size in the range from 0.01 to 20 microns but preferably 0.01 to 10 microns.

In some embodiments the low white or low coloured layer, or combined layers, diffuses at least 1 %, 2%, 3%, 4%, 5%, 6%, 7% 8%, 9%, 10%, 15%, 20%, 25%, 30%, 35%, 40%, 45%, 50%, 55%, 60%, 65%, 70%, 75%, 80%, 85%, 90% or 95% or more of direct light incident on the low white-or low colour translucent layer, or layers, and which is reflected back from the metallized layer.

In some embodiments the low white or low coloured layer, or layers, does not diffuse at least 5%, 10%, 20%, 30%, 40%, or 50% or more of direct light incident on the low white or low coloured translucent layer, or layers, and which is reflected back from the metallized layer.

In some embodiments the white pigment(s) additionally comprise in addition to the white pigment(s), coloured pigments or dyes which will typically reflect UV as well as visible light, a UV absorbing white pigment or dye or partially UV absorbing pigment, such as but not limited to titanium dioxide. The UV absorbing white pigment may comprise 0.01 to 12% by weight of the clear or translucent layer, such as 0.001 %, 0.1 %, 0.2%, 0.25%,

In some embodiments the white pigment(s) additionally comprise in addition to the white pigment and/or coloured pigment or dye, which will typically reflect UV as well as visible light, a NIR reflecting white pigment, such as titanium dioxide. The NIR reflecting white pigment may comprise 0.01 to 3% by weight of the clear or translucent layer, such as 0.01%, 0.1%, 0.2%, 0.25%, 0.3%, 0.35%, 0.4%, 0.45%, 0.5%, 0.55% 0.6%, 0.65%, 0.7%, 0.75%, 0.8%, 0.85%, 0.9%, 0.95%, 1%, 1.5%, 2%, 2.5% or 3% or 4% or 5% or 6% or 7% or 8% or 10% or 11% or 12% by weight.

In some embodiments the white pigment(s) additionally comprise in addition to the white pigment, which will typically reflect UV as well as visible light, a NIR reflecting white pigment, such as titanium dioxide. The IR reflecting white pigment may comprise 0.01 to 3% by weight of the clear or translucent layer, such as 0.1%, 0.2%, 0.25%, 0.3%, 0.35%, 0.4%, 0.45%, 0.5%, 0.55% 0.6%, 0.65%, 0.7%, 0.75%, 0.8%, 0.85%, 0.9%, 0.95%, 1%, 1.5%, 2%, 2.5% or 3% or 4% or 5% or 6% or 7% or 8% or 10% or 11% or 12% by weight.

In some embodiments the transparent or translucent polymer containing the white pigment and/or coloured pigments and/or dyes comprises a polyolefin, polyethylene, polypropylene, polyester, polystyrene, polyamide, polyethylene terephthalate, polyvinyl chloride, polylactic acid, polyhydroxalkanoate, polybutyrate, polycaprolactone, polyvinyl alcohol, starch, cellulose and/or polybutylene succinate, and/or a biodegradable material such as an aliphatic polyester, chitosan, polyester amide, polybutylene succinate-co-adipate, or polybutylene adipate terephthalate. The transparent or translucent polymer containing the white pigment (and/or any other polymer layer of the material) may be a biaxially-oriented or monoaxially-oriented film material ; may be a blown film material or a cast film; and may be a biodegradable film material.

### Metallized Layer

The metallized layer comprises an aluminium film layer or a layer of another metal such as antimony, silver, zinc or other metal and deposited for example by vapour deposition.

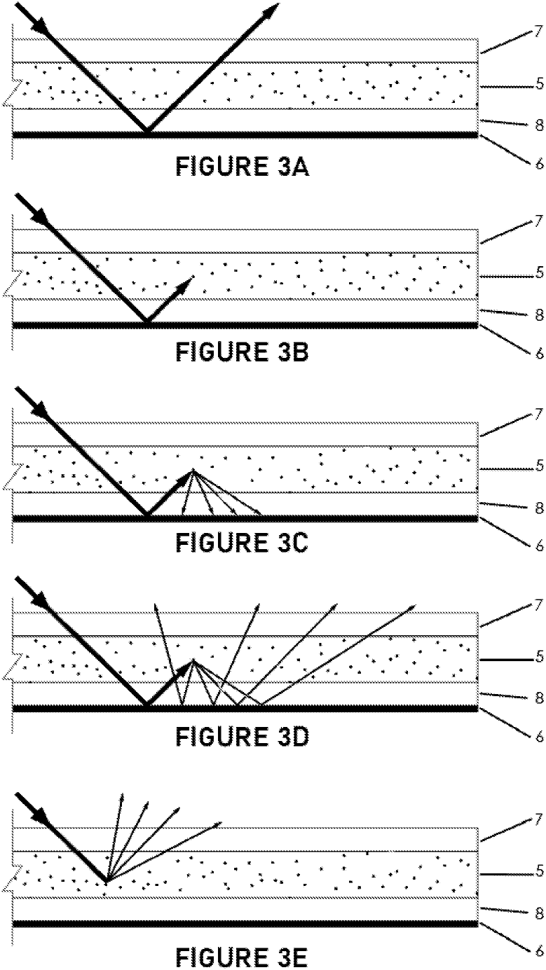

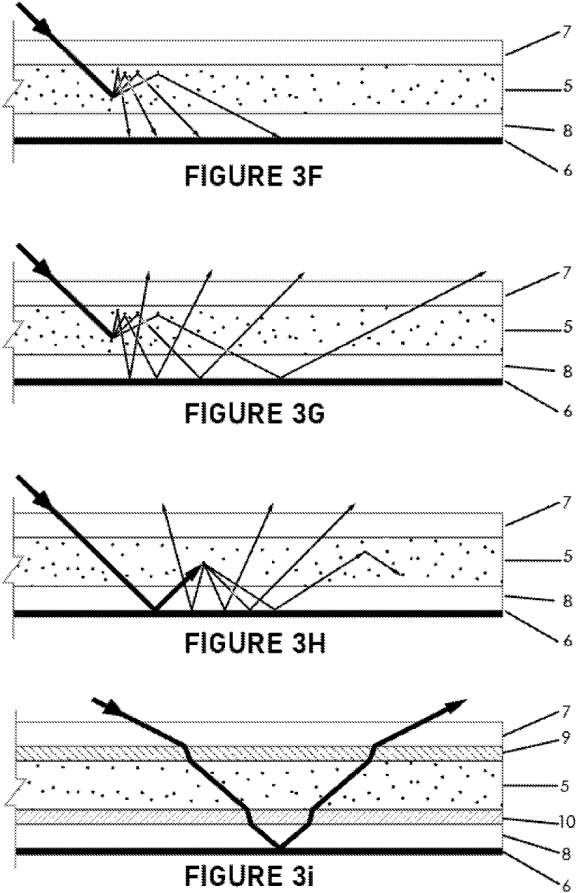

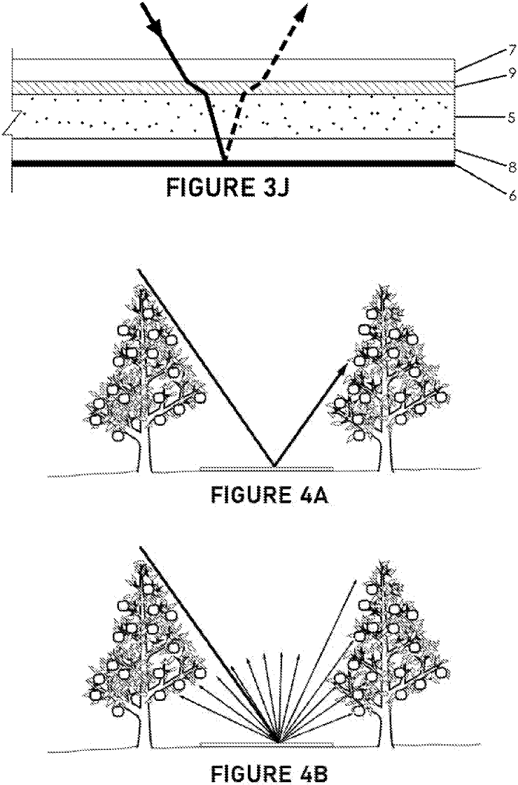

Referring to FIGS. 3A-J which are cross-section views of a portion of the ground cover material of FIG. 2B schematically showing light reflection diffusion within the material in use, the material is placed on the ground beneath or between rows of trees, vines, or other plants, with the low white-translucent low or coloured-translucent side 5 up and the metallized side 6 down.

As illustrated in FIG. 3A, some solar radiation/light incident on the material passes through the low white-translucent or low coloured-translucent layer 5 without reflection/diffusion within that layer 5, and is reflected by the metallized layer 6 back though the low white-translucent layer 5, again without reflection/diffusion within that layer 5.

As illustrated in FIGS. 3B-D, some solar radiation/light incident on the material passes through the low white-translucent or low coloured-translucent layer 5 without reflection/diffusion within that layer 5, and is reflected by the metallized layer 6 back though the low white-translucent or low coloured-translucent layer 5 - see FIG. 3B, but then is reflected diffusely or diffused by pigment particles within that layer 5 back towards the metallized layer 6 - see FIG. 3C, where it is again reflected back through the low white-translucent layer 5 - see FIG. 3D.

As illustrated in FIG. 3E, some solar radiation/light incident on the material entering the low white-translucent or low coloured-translucent layer 5 is reflected diffusely or diffused by pigment particles within that layer 5 back through the low white-translucent layer 5.

As illustrated in FIGS. 3F and G, some solar radiation/light incident on the material entering the low white-translucent or low coloured-translucent layer 5 is reflected diffusely or diffused by pigment particles within that layer 5, is re-reflected diffusely or diffused by pigment particles within that layer 5, towards the metallized layer 6 - see FIG. 3F, where it is again reflected back through the low white-translucent or low coloured-translucent layer 5 - see FIG. 3G.

As illustrated in FIG. 3H, some solar radiation/light incident on the material passes through the low white-translucent or low coloured-translucent layer 5 without reflection/diffusion within that layer 5, is reflected by the metallized layer 6 back though the low white-translucent or low coloured-translucent layer 5, is re-reflected diffusely or diffused by pigment particles within that layer 5, towards the metallized layer 6, where it is again reflected back through the low white-translucent or low coloured-translucent layer 5. As illustrated in FIG. 3H, some energy from the solar radiation/light entering the low-white or low-coloured translucent layer 5 and reflected off the metal layer is diffused and absorbed in layer 5, thus the wave energy reflected back to the plants is reduced.

As illustrated in FIG. 31, some solar radiation/light incident on the material entering the layer 9 loses energy as it passes through layer 9, a low-colour pigment or dye layer, then loses further energy as it passes through layers 5 and 10, low-colour pigment or dye layers. The light passes to the metallized layer where it is reflected back through the layers where it loses further energy before reflecting back to the plants at lower or diffuse energy.

As illustrated in FIG. 3J, some solar radiation/light incident on the material passes through the first low white-translucent or low-coloured-translucent layer 9, with some reflection/diffusion/absorption within layer 9, then passes through the second low white-translucent or low-coloured-translucent layer 5, with some reflection/diffusion/absorption within layer 5, is reflected back again by the metallized layer 6 back through the low white or low-coloured translucent layer 5 and layer 9 with some reflection/diffusion/absorption within layer 9 and layer 5.

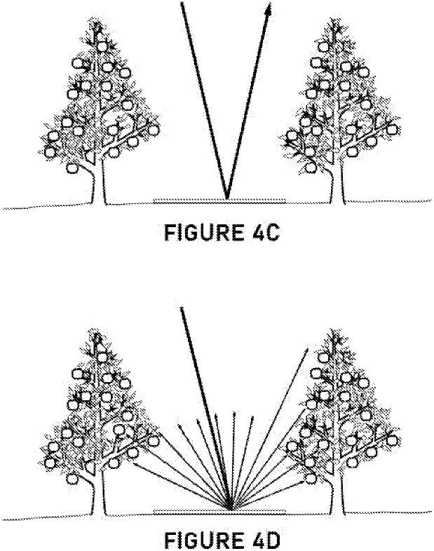

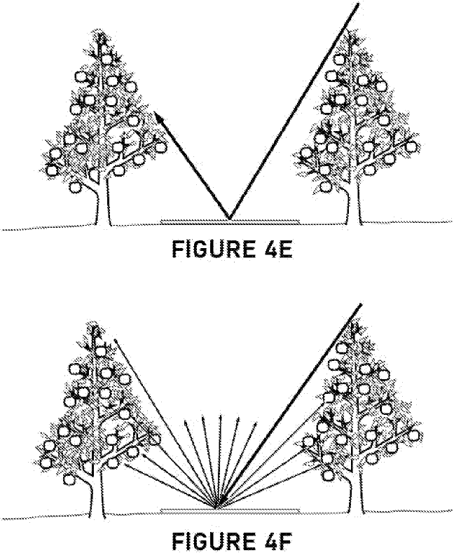

Referring to FIGS. 4A-F which show direct and diffuse reflection of solar radiation from the material which is placed on the ground beneath or between rows of trees, vines, or other plants, with the low white-translucent low coloured-translucent side 5 up and the metallized side 6 down.

As illustrated in FIG. 4A, solar radiation/light incident on the material in the morning is reflected directly towards a localized area of the tree canopy on the opposite side of the row.

As illustrated in FIG. 4B, solar radiation/light incident on the material in the morning is also reflected but diffusely, wherein light is scattered and diffusely reflected at all angles towards the tree canopies on either side of the row. A portion of diffuse light passes between leaves and branches to the inner canopy.

As illustrated in FIG. 4C, solar radiation/light incident on the material at solar midday is reflected directly light at a sharp angle such that the reflected light may not hit the tree canopy and is unable to be captured by the tree.

As illustrated in FIG. 4D, solar radiation/light incident on the material at solar midday is reflected diffusely, wherein light is scattered and diffusely reflected at all angles towards the tree canopies on either side of the row. A portion of diffuse light passes between leaves and branches to the inner canopy.

As illustrated in FIG. 4E, solar radiation/light incident on the material in the afternoon is reflected directly towards a localized area of the tree canopy on the opposite side of the row.

As illustrated in FIG. 4F, solar radiation/light incident on the material in the afternoon is reflected diffusely, wherein light is scattered and diffusely reflected at all angles towards the tree canopies on either side of the row. A portion of diffuse light passes between leaves and branches to the inner canopy.

Thus, solar radiation/light incident on the material is both directly and diffusely reflected and absorbed by the material. A proportion of light incident on the material is reflected back to plants, however a proportion of this reflected light is diffusely reflected or diffused not directly reflected. This is advantageous as an amount of light is reflected back to plants but the likelihood of fruit burn is reduced, and light distribution is enhanced in the plant and around the fruit, providing more even fruit colouration.

### Light Diffusion

Preferably the low white-translucent or low coloured-translucent layer, or layers, transmits at least 50%, or 60% or 70%, 80% more preferably greater than 90% or 95% of light (UV, visible, NIR and IR) entering the material.

In at least some embodiments the amount of the white pigment or pigments, and/or the clarity or translucence of the polymer before addition of the white pigment(s), is such that the low white-translucent or low coloured-translucent layer will diffuse at least 1%, 5%, 10%, 15%, 20%, 25%, 30%, 35%, 40%, 45%, 50%, 55%, 60%, 65%, 70%, 75%, 80%, 85%,90% or 95% or more of direct light incident on the low white-translucent or low coloured-translucent layer, or layers, and which passes through it and is reflected back through it by the metal layer.

Light incident on the low white-translucent or low coloured-translucent layer, or layers, and which is not diffusely or diffuse reflected back through it may be either directly reflected back through it, or absorbed or altered in the low white-translucent or low coloured-translucent layer, or layers. In at least some embodiments the amount of the white or coloured pigment/dye or pigments/dyes is such that the low white-translucent or low coloured-translucent layer will not diffuse at least 1%, 5%, 10%, 15%, 20%, 30%, 40%, 50%, 60%, 70%, 80% or 90% or more of direct light incident on the low white-translucent layer and which passes through it and is reflected back through it by the metal layer.

### Optical Properties of the Low White-Translucent or Low Coloured-Translucent Layer

Some UV light and/or infrared light may be absorbed in the low white-translucent or low coloured-translucent layer, or layers.

In one embodiment the low white-translucent or low coloured-translucent layer:
absorbs and/or transmits more solar radiation than it diffusely reflects or diffuses in the UV range of about 280-400 nm, and
transmits at least part of solar radiation in the range about 800-2500 nm and at least part of solar radiation above about 2500 nm, and

The low white-translucent or low coloured-translucent layer may diffusely reflect or induce diffusion at least about 10% of solar radiation in the infrared range of about 1000-1500 nm. The low white-translucent or low coloured-translucent layer may diffusely reflect at least about 20% of solar radiation in the infrared range of about 1500-2000 nm.

The reflectance and transmittance of the low white-translucent or low coloured-translucent layer and any adjoining non-pigmented layers but not the metallized layer may be as shown in any of the tables below:

| Wavelength nm | Reflectance | Transmittance |
|---|---|---|
| 280-420 | 1 to 50% | 30 to 95% |
| 421-700 | 1 to 50% | 30 to 95% |

| Wavelength nm | Reflectance | Transmittance |
|---|---|---|
| 280-420 | 5 to 40% | 30 to 90% |
| 421-700 | 5 to 40% | 30 to 90% |

| Wavelength nm | Reflectance | Transmittance |
|---|---|---|
| 280-420 | 10 to 30% | 40 to 85% |
| 421-700 | 10 to 30% | 40 to 85% |

In an embodiment the low white-translucent or low coloured-translucent layer may comprise at least one main white UV reflecting or diffusing pigment, and at least one UV absorbing/diffusing co-pigment in an amount that decreases the reflectance of the white film at 280 nm-400 nm compared to the same material without the co-pigment due to increasing the UV absorbance of the material.

In an embodiment the low white-translucent or low coloured-translucent layer may comprise:
at least one UV reflecting and/or diffusing white main pigment,
at least one inorganic white UV absorbing and/or diffusing pigment, and at least one organic UV absorbing pigment,
optionally also a (non-white) coloured pigment or dye,
the UV absorbing pigments decreasing the reflectance in the UV range of about 280 nm-400 nm compared to the same material without the UV absorbing pigments due to increasing the UV absorbance of the material. In an embodiment the low white-translucent or low coloured-translucent layer comprises least one inorganic clear or substantially clear UV absorbing pigment. In an embodiment the low white-translucent or low coloured-translucent layer comprises UV absorbing pigments which decrease the surface reflectance in the UV range of about 280 nm-400 nm.

In another embodiment of a ground cover sheet material the low white-translucent or low coloured-translucent layer:
absorbs or transmits more solar radiation than it reflects in the UV range of about 280-400 nm, and reflects at least 10% in the visible range of about 400-700 nm and near infrared range of about 700-800 nm,
transmits at least part of solar radiation in the range about 800-2500 nm and at least part of solar radiation above about 2500 nm, and
reflects at least about 10% of solar radiation in the infrared range of about 700-1000 nm.

The low white-translucent or low coloured-translucent layer may reflect and/or diffuse at least about 10% of solar radiation in the infrared range of about 1000-1500 nm. The low white-translucent or low coloured-translucent layer may reflect and/or diffuse at least about 10% of solar radiation in the infrared range of about 1500-2000 nm.

In an embodiment the reflectance and transmittance of the low white-translucent or low coloured-translucent layer and any adjoining non-pigmented layers but not the metallized layer is as shown in any of the tables below:

| Wavelength nm | Reflectance | Transmittance |
|---|---|---|
| 280-420 | 5 to 50% | 50 to 95% |
| 421-700 | 10 to 90% | 5 to 90% |

| Wavelength nm | Reflectance | Transmittance |
|---|---|---|
| 280-420 | 10 to 40% | 60 to 90% |
| 421-700 | 10 to 80% | 10 to 60% |

| Wavelength nm | Reflectance | Transmittance |
|---|---|---|
| 280-420 | 15 to 30% | 70 to 85% |
| 421-700 | 10 to 70% | 20 to 60% |

In an embodiment the low white-translucent or low coloured-translucent layer may comprise at least one main white UV reflecting and/or diffusing pigment, and at least one UV absorbing co-pigment in an amount that decreases the reflectance of the white film at 280 nm-400 nm compared to the same material without the co-pigment due to increasing the UV absorbance of the material.

In an embodiment the low white-translucent or low coloured-translucent layer may comprise:
at least one UV reflecting and/or diffusing white main pigment, and
at least one organic UV absorbing and/or diffusing pigment, the UV absorbing and/or diffusing pigment decreasing the reflectance in the UV range of about 280 nm-400 nm of the white film compared to the same material without the UV absorbing pigments due to increasing the UV absorbance of the material.

In an embodiment the low white-translucent or low coloured-translucent layer comprises least one organic UV absorbing and/or diffusing pigment. In an embodiment the white layer comprises UV absorbing and/or diffusing pigment which decrease the surface reflectance in the UV range of about 280 nm-400 nm.

In a further embodiment of a ground cover sheet material the low white-translucent or low coloured-translucent layer:
reflects and/or diffuses at least 20% in the UV range of about 280-400 nm, and reflects at least 30% in the visible range of about 400-700 nm and near infrared range of about 700-800 nm,
transmits and/or diffuses at least part of solar radiation in the range about 800-2500 nm and at least part of solar radiation above about 2500 nm, and
reflects and/or diffuses at least about 30% of solar radiation in the infrared range of about 700-1000 nm.

The low white-translucent or low coloured-translucent layer may reflect and/or diffuses at least about 20% of solar radiation in the infrared range of about 1000-1500 nm. The low white-translucent or low coloured-translucent layer may reflect at least about 20% of solar radiation in the infrared range of about 1500-2000 nm.

In an embodiment the reflectance and transmittance of the low white-translucent or low coloured-translucent layer and any adjoining non-pigmented layers but not the metallized layer is as shown in any of the tables below:

| Wavelength nm | Reflectance | Transmittance |
|---|---|---|
| 280-420 | 0 to 80% | 5 to 90% |
| 421-700 | 0 to 90% | 5 to 90% |

| Wavelength nm | Reflectance | Transmittance |
|---|---|---|
| 280-420 | 10 to 70% | 30 to 90% |
| 421-700 | 10 to 80% | 20 to 90% |

| Wavelength nm | Reflectance | Transmittance |
|---|---|---|
| 280-420 | 10 to 60% | 40 to 90% |
| 421-700 | 10 to 70% | 30 to 90% |

In an embodiment the low white-translucent or low coloured-translucent layer comprises at least one main white UV reflecting and/or diffusing pigment or dye. In an embodiment the low white-translucent or low coloured-translucent layer comprises at least one UV reflecting and/or diffusing white main pigment.

In a further embodiment of a ground cover sheet material the low white-translucent or low coloured-translucent layer:
absorbs or transmits more solar radiation than it reflects and/or diffuses in the UV range of about 280-400 nm, and reflects at least 30% in the visible range of about 400-700 nm and near infrared range of about 700-800 nm,
transmits at least part of solar radiation in the range about 800-2500 nm and at least part of solar radiation above about 2500 nm, and
reflects and/or diffuses at least about 30% of solar radiation in the infrared range of about 700-1000 nm.

The low white-translucent or low coloured-translucent layer may reflect and/or diffuses at least about 20% of solar radiation in the infrared range of about 1000-1500 nm. The white layer may reflect and/or diffuses at least about 20% of solar radiation in the infrared range of about 1500-2000 nm.

In a further embodiment of a ground cover sheet material the low white or low-colour translucent layer in any of the embodiments can also comprise of more than one layer of low-white or low-colour pigment or dye.

In an embodiment the reflectance and transmittance of the low white-translucent or low coloured-translucent layer and any adjoining non-pigmented layers but not the metallized layer is shown in any of the tables below:

| Wavelength nm | Reflectance | Transmittance |
|---|---|---|
| 280-420 | 0 to 50% | 0 to 90% |
| 421-700 | 00 to 90% | 5 to 90% |

| Wavelength nm | Reflectance | Transmittance |
|---|---|---|
| 280-420 | 0 to 40% | 0 to 90% |
| 421-700 | 10 to 80% | 20 to 90% |

| Wavelength nm | Reflectance | Transmittance |
|---|---|---|
| 280-420 | 0 to 30% | 0 to 90% |
| 421-700 | 10 to 70% | 30 to 90% |

### Optical Properties of the Metallized Reflective Film With Low White-Translucent or Low Coloured-Translucent Side on Top

In a further embodiment, a ground cover sheet material comprising a low white-translucent or low coloured-translucent side and a metallized side that when placed low white-translucent or low coloured-translucent side up, provides a portion of diffusely reflected light and a portion of directly reflected light:
reflects diffuse and direct light in the UV range of about 280-400 nm, with at least 5% of reflected light being diffuse light
reflects diffuse and direct light in the visible range of about 421-700 nm, with at least 5% of reflected light being diffuse light

| Wavelength nm | Diffuse reflectance | Direct Reflectance |
|---|---|---|
| 280-420 | 5 - 90% | 25 - 95% |
| 421-700 | 5 - 90% | 25 - 95% |

In a further embodiment, a ground cover sheet material comprising a low white-translucent or low coloured-translucent side and a metallized side that when placed low white-translucent or low coloured-translucent side up, provides a portion of diffusely reflected light and a portion of directly reflected light:
reflects diffuse and direct light in the UV range of about 280-400 nm, with at least 10% of reflected light being diffuse light
reflects diffuse and direct light in the visible range of about 421-700 nm, with at least 10% of reflected light being diffuse light

| Wavelength nm | Diffuse reflectance | Direct Reflectance |
|---|---|---|
| 280-420 | 10 - 90% | 20 - 90% |
| 421-700 | 10 - 90% | 20 - 90% |

In a further embodiment, a ground cover sheet material comprising a low white-translucent or low coloured-translucent side and a metallized side that when placed low white-translucent or low coloured-translucent side up, provides a portion of diffusely reflected light and a portion of directly reflected light:
reflects diffuse and direct light in the UV range of about 280-400 nm, with at least 15% of reflected light being diffuse light
reflects diffuse and direct light in the visible range of about 421-700 nm, with at least 15% of reflected light being diffuse light

| Wavelength nm | Diffuse reflectance | Direct Reflectance |
|---|---|---|
| 280-420 | 15 - 90% | 15 - 85% |
| 421-700 | 15 - 90% | 15 - 85% |

In a further embodiment, a ground cover sheet material comprising a low white-translucent or low coloured-translucent side and a metallized side that when placed low white-translucent or low coloured-translucent side up, provides a portion of diffusely reflected light and a portion of directly reflected light:
reflects diffuse and direct light in the UV range of about 280-400 nm, with at least 20% of reflected light being diffuse light
reflects diffuse and direct light in the visible range of about 421-700 nm, with at least 20% of reflected light being diffuse light

| Wavelength nm | Diffuse reflectance | Direct Reflectance |
|---|---|---|
| 280-420 | 20 - 90% | 10 - 80% |
| 421-700 | 20 - 90% | 10 - 80% |

In a further embodiment, a ground cover sheet material comprising a low white-translucent or low coloured-translucent side and a metallized side that when placed low white-translucent or low coloured-translucent side up, provides a portion of diffusely reflected light and a portion of directly reflected light:
reflects diffuse and direct light in the UV range of about 280-400 nm, with at least 25% of reflected light being diffuse light
reflects diffuse and direct light in the visible range of about 421-700 nm, with at least 25% of reflected light being diffuse light

| Wavelength nm | Diffuse reflectance | Direct Reflectance |
|---|---|---|
| 280-420 | 25 - 90% | 10 - 75% |
| 421-700 | 25 - 90% | 10 - 75% |

In a further embodiment, a ground cover sheet material comprising a low white-translucent or low coloured-translucent side and a metallized side that when placed low white-translucent or low coloured-translucent side up, provides a portion of diffusely reflected light and a portion of directly reflected light:
reflects diffuse and direct light in the UV range of about 280-400 nm, with at least 30% of reflected light being diffuse light
reflects diffuse and direct light in the visible range of about 421-700 nm, with at least 30% of reflected light being diffuse light

| Wavelength nm | Diffuse reflectance | Direct Reflectance |
|---|---|---|
| 280-420 | 30 - 90% | 10 - 70% |
| 421-700 | 30 - 90% | 10 - 70% |

In a further embodiment, a ground cover sheet material comprising a low white-translucent or low coloured-translucent side and a metallized side that when placed low white-translucent or low coloured-translucent side up, provides a portion of diffusely reflected light and a portion of directly reflected light:
reflects diffuse and direct light in the UV range of about 280-400 nm, with at least 40% of reflected light being diffuse light
reflects diffuse and direct light in the visible range of about 421-700 nm, with at least 40% of reflected light being diffuse light

| Wavelength nm | Diffuse reflectance | Direct Reflectance |
|---|---|---|
| 280-420 | 40 - 90% | 10 - 60% |
| 421-700 | 40 - 90% | 10 - 60% |

In a further embodiment, a ground cover sheet material comprising a low white-translucent or low coloured-translucent side and a metallized side that when placed low white-translucent or low coloured-translucent side up, provides a portion of diffusely reflected light and a portion of directly reflected light:
reflects diffuse and direct light in the UV range of about 280-400 nm, with at least 50% of reflected light being diffuse light
reflects diffuse and direct light in the visible range of about 421-700 nm, with at least 50% of reflected light being diffuse light

| Wavelength nm | Diffuse reflectance | Direct Reflectance |
|---|---|---|
| 280-420 | 50 - 90% | 10 - 50% |
| 421-700 | 50 - 90% | 10 - 50% |

In a further embodiment, a ground cover sheet material comprising a low white-translucent or low coloured-translucent side and a metallized side that when placed low white-translucent or low coloured-translucent side up, provides a portion of diffusely reflected light and a portion of directly reflected light:
reflects diffuse and direct light in the UV range of about 280-400 nm, with at least 50% of reflected light being diffuse light
reflects diffuse and direct light in the visible range of about 421-700 nm, with at least 30% of reflected light being diffuse light

| Wavelength nm | Diffuse reflectance | Direct Reflectance |
|---|---|---|
| 280-420 | 50 - 90% | 10 - 50% |
| 421-700 | 30 - 70% | 30 - 70% |

In a further embodiment, a ground cover sheet material comprising a low white- translucent or low coloured-translucent side and a metallized side that when placed low white-translucent or low coloured-translucent side up, provides a portion of diffusely reflected light and a portion of directly reflected light:
reflects diffuse and direct light in the UV range of about 280-400 nm, with at least 60% of reflected light being diffuse light
reflects diffuse and direct light in the visible range of about 421-700 nm, with at least 50% of reflected light being diffuse light

| Wavelength nm | Diffuse reflectance | Direct Reflectance |
|---|---|---|
| 280-420 | 50 - 90% | 10 - 50% |
| 421-700 | 20 - 60% | 40 - 80% |

In a further embodiment, a ground cover sheet material comprising a low white-translucent or low coloured-translucent side and a metallized side that when placed low white-translucent or low coloured-translucent side up, provides a portion of diffusely reflected light and a portion of directly reflected light:
reflects diffuse and direct light in the UV range of about 280-400 nm, with at least 50% of reflected light being diffuse light
reflects diffuse and direct light in the visible range of about 421-700 nm, with at least 50% of reflected light being diffuse light

| Wavelength nm | Diffuse reflectance | Direct Reflectance |
|---|---|---|
| 280-420 | 40 - 80% | 20 - 60% |
| 421-700 | 30 - 70% | 30 - 70% |

In a further embodiment, a ground cover sheet material comprising a low white-translucent or low coloured-translucent side and a metallized side that when placed low white-translucent or low coloured-translucent side up, provides a portion of diffusely reflected light and a portion of directly reflected light:
reflects diffuse and direct light in the UV range of about 280-400 nm, with at least 50% of reflected light being diffuse light
reflects diffuse and direct light in the visible range of about 421-700 nm, with at least 50% of reflected light being diffuse light

| Wavelength nm | Diffuse reflectance | Direct Reflectance |
|---|---|---|
| 280-420 | 40 - 80% | 20 - 60% |
| 421-700 | 40 - 60% | 40 - 80% |

In a further embodiment, a ground cover sheet material comprising more than one layer of low-colour translucent pigments or dyes and a metallized side that when placed low-colour translucent side up, provides a portion of diffusely reflected light and a portion of directly reflected light:
reflects diffuse and direct light in the UV range of about 280-400 nm, with at least 5% of reflected light being diffuse light
reflects diffuse and direct light in the visible range of about 421-700 nm, with at least 5% of reflected light being diffuse light
absorbs and reflects diffuse and direct light in the UV and visible range of about 280-700 nm, with at least 5% of reflected light being diffuse light
reflects diffuse and direct light in the IR range of about 700-2500 nm, with at least 5% of reflected light being diffuse light

| Wavelength nm | Diffuse reflectance | Direct Reflectance |
|---|---|---|
| 280-420 | 5 - 90% | 25 - 95% |
| 421-700 | 5 - 90% | 25 - 95% |
| 700-2500 | 5 - 90% | 25 - 95% |

Absorbs direct light and reflects diffuse and direct light in the UV and IR range of about 280-2500 nm, with at least 5% of reflected light being diffuse light.

| Wavelength nm | Absorbance | Diffuse Reflectance | Direct Reflectance |
|---|---|---|---|
| 280-420 | 5 - 90% | 5 - 90% | 25 - 95% |
| 42 1-700 | 5 - 90% | 5 - 90% | 25 - 95% |
| 700-2500 | 5 - 90% | 5 - 90% | 25 - 95% |

### EXAMPLES - TRIALS

### Reflective Film Effects on Fruit Colouration of Kanzi Apples

A field trial was carried out on Kanzi apples in the Hawkes Bay, New Zealand to determine the impact of the different reflective films according to the disclosure on foreground and background fruit colouration.

The rows were running from East to West. The rows were at 3.9 metre spacing in a tall spindle trellis system. The tree spacing was 1.5 metres. The 2.0 m wide film was installed under approximately 50 trees with the white layer on top and aluminium layer on bottom expect for one test with the aluminium layer was on the top. The reflective films according to the disclosure were assessed against conventional metallized film with the metallized side up and the clear polymer side up to cover both options.

The film was applied on the 26 Feb. 2021. The fruit were harvested on the 6 Mar. 2021 and blush intensity (redness of fruit), blush coverage (percent surface area of fruit covered with red colouring), background colour (indicator of internal fruit maturity). Forty fruit were assessed per treatment. The first 20 fruit were taken from the outside layer of the canopy, and the second 20 fruit were taken from within the canopy.

Five films were trialled:

No Film - No film was placed over the ground area between the trees (this was occupied by mixed grasses - where films were applied they were placed over these grasses).

Film 1 - Reflective film with metallized layer and low white-translucent layer side up, containing 0.4% TiO₂

Film 2 - Reflective film with metallized layer and low white-translucent layer side up, containing 0.6% TiO₂

Film 3 - Reflective film with metallized layer and low white-translucent layer side up, containing 1.1% TiO₂

Film 4 - Conventional aluminium reflective film with clear base polymer, with metallized layer side up.

Film 5 - Conventional aluminium reflective film with clear base polymer, with polymer side up. Film 5 was the same as Film 4 but was placed with the opposite side up, that is: film 4 - placed with metallized layer up, film 5 placed with metallized layer down.

The tables below show the results of reflective film on blush intensity and coverage, background colour and (BGC) in Kanzi™ apples. Two-tailed T tests were completed assuming equal variance. Lower-case letters represent a significant difference at <0.05.

Comparison 1

| Treatment | Outer Blush Intensity | Outer Blush Coverage | Outer BGC | Inner Blush Intensity | Inner Blush Coverage | Inner BGC |
|---|---|---|---|---|---|---|
| No Film | 8.90 b | 75.50 b | 2.25 b | 7.40 b | 71.25 a | 1.90 a |
| Film 4 | 9.65 a | 82.25 a | 2.70 a | 8.70 a | 70.75 a | 2.20 a |
| P value | <0.01 | <0.01 | 0.01 | <0.01 | 0.85 | 0.09 |

Film 4 (aluminium with aluminium side up) enhanced fruit colouration. There were commercially significant increases in the blush coverage (75.50 to 82.25) and the blush intensity (8.90 to 9.65) for fruit in the outer canopy (to be anticipated, noting the widespread use of this type of material in the industry to enhance fruit colour). The Blush Coverage (measure of the spread of colour on the apple) of fruit in the inner canopy was not impacted like the Blush Intensity (measures the concentration of red colour on the apple) did not increase as light was directly reflected from Film 4 and was not diffused through the tree canopy. The Blush Intensity of fruit in the inner canopy increased due to increased light around the tree. The Background Colour of the fruit was higher in both the outer and inner canopy was higher with Film 4, indicating more advanced fruit maturity due to direct heat reflectivity from the Film 4.

Comparison 2

| Treatment | Outer Blush Intensity | Outer Blush Coverage | Outer Back Ground Colour | Inner Blush Intensity | Inner Blush Coverage | Inner Back Ground Colour |
|---|---|---|---|---|---|---|
| Film 4 | 9.65 a | 82.25 a | 2.70 a | 8.70 a | 70.75 a | 2.20 a |
| Film 5 | 9.40 a | 81.25 a | 2.60 a | 7.40 b | 69.25 a | 2.45 a |
| P value | 0.19 | 0.66 | 0.62 | <0.01 | 0.57 | 0.10 |

Film 5 (clear base polymer up with the conventional aluminium reflective film) gave a similar result to Film 4.

Comparison 3

| Treatment | Outer Blush Intensity | Outer Blush Coverage | Outer Back Ground Colour | Inner Blush Intensity | Inner Blush Coverage | Inner Back Ground Colour |
|---|---|---|---|---|---|---|
| Film 5 | 9.40 a | 81.25 a | 2.60 a | 7.40 b | 69.25 a | 2.45 a |
| Film 1 | 9.65 a | 81.75 a | 2.60 a | 8.45 a | 72.25 a | 2.35 a |
| P value | 0.22 | 0.85 | 1.00 | 0.01 | 0.33 | 0.53 |

Film 1 (metallized layer and low white-translucent layer side up, containing 0.4% TiO₂) increased light diffusion and provided enhanced fruit colouration compared to Film 5. Film 1 had improved Blush Intensity and Blush Coverage compared to Film 5. The benefits of increased light diffusion are most evident for Blush Intensity and Blush Coverage in the inner canopy, where diffuse light had a higher penetration.

Comparison 4

| Treatment | Outer Blush Intensity | Outer Blush Coverage | Outer Back Ground Colour | Inner Blush Intensity | Inner Blush Coverage | Inner Back Ground Colour |
|---|---|---|---|---|---|---|
| Film 5 | 9.40 b | 81.25 a | 2.60 a | 7.40 b | 69.25 a | 2.45 a |
| Film 2 | 9.90 a | 83.75 a | 2.60 a | 8.60 a | 71.75 a | 2.05 b |
| P value | <0.01 | 0.31 | 1.00 | <0.01 | 0.37 | <0.01 |

Film 2 (metallized layer and low white-translucent layer side up, containing 0.6% TiO₂) had significantly higher Blush Intensity and increased Blush Coverage in the inner and outer canopy. Fruit colouration was enhanced compared to Film 5. In addition, the Background Colour has reduced significantly in fruit in the inner canopy, showing a reduction in heat.

Delayed maturity with better colour at this stage is considered advantageous for fruit storage and long term eating quality.

Comparison 5

| Treatment | Outer Blush Intensity | Outer Blush Coverage | Outer Back Ground Colour | Inner Blush Intensity | Inner Blush Coverage | Inner Back Ground Colour |
|---|---|---|---|---|---|---|
| Film 5 | 9.40 a | 81.25 a | 2.60 a | 7.40 a | 69.25 a | 2.45 a |
| Film 3 | 9.30 a | 83.00 a | 2.75 a | 7.65 a | 69.50 a | 2.15 b |
| P value | 0.64 | 0.46 | 0.45 | 0.37 | 0.94 | 0.04 |

Film 3 (metallized layer and low white-translucent layer side up, containing 1.1% TiO₂) provided improved Blush Intensity and Blush Coverage compared Film 5. In addition, the Background Colour reduced significantly in fruit in the inner canopy, showing a reduction in heat compared to Film 5 above. Delayed maturity with better colour at this stage is considered advantageous for fruit storage and long term eating quality.

Conventional aluminium reflective film ground cover currently used in the horticultural industry has limitations in that it reflects mostly spectral light. This is evident from performance depending on which side of the film is up, that is if the film has the aluminium side up as in Film 4 or is the base polymer side up as in Film 5. The results show that the reflective film of the disclosure has reflective properties that are advantageous for colouration of Kanzi apples. These improvements are visibly different, commercially significant and offer increased financial yields to growers.

According to various embodiments, the following is provided.

A ground cover material having a greater length than width and comprising:

on one side a low white layer or layers comprising or composed of a transparent or translucent polymer and a low amount of a white pigment (or pigments) such that the low white layer, or layers, is white-translucent, and on an opposite side a metallized layer.

A ground cover material having a greater length than width and comprising:
a low white layer that includes a translucent polymer and a low amount of a white pigment (or pigments) such that the low white layer, or layers, is white-translucent, and
on an opposite side a metallized layer.

A ground cover material wherein the low white layer, or layers, comprises a white pigment in an amount up to 0.1% or 0.2% or 0.3%, 0.4%, 0.5%, 0.6%, 0.7%, 0.8%, 0.9%, 1.0%, 1.1%, 1.2%, 1.3%, 1.4%, 1.5%, 1.6%, 1.7%, 1.8%, 1.9% or 2.0% by weight of the low white layer, or in an amount up to half of said percentage amounts by weight of the whole material.

A ground cover material wherein the low white layer, or layers, comprises a white pigment in an amount not more than 20%, 15%, 10%, 5%, 4%, 2%, 1%, 0.5%, 0.2%, 0.01% or 0.001% by weight of the low white layer, or in an amount not more than 20%, 15%, 10%, 5%, 4%, 2%, 1%, 0.5% 0.2%, 0.01% or 0.001% by weight of the whole material.

A ground cover material wherein the low white layer comprises at least one main white UV reflecting pigment, and at least one UV absorbing co-pigment.

A ground cover material wherein the UV absorbing pigment is an inorganic pigment.

A ground cover material wherein the UV absorbing co-pigment is an organic pigment.

A ground cover material wherein the low white layer, or layers, comprises at least one main white IR reflecting pigment

A ground cover material wherein the low white layer, or layers, comprises at least one main white IR absorbing pigment

A ground cover material wherein the white pigment is chosen from the group titanium, titanate, zirconium, silica, strontium, zinc, barium, potassium, calcium, magnesium and sodium.

A ground cover material wherein the white pigment is an oxide.

A ground cover material having a greater length than width and comprising:
on one side a translucent layer, or layers, comprising or composed of a transparent or translucent polymer and a low amount of a white pigment (or pigments) and a low amount of coloured pigment or dye such that the translucent layer is white-translucent or coloured-translucent, and
on an opposite side a metallized layer.

A ground cover material wherein the translucent layer, or layers, comprises a pigment (or pigments) in an amount up to 0.001% or 0.1% or 0.2% or 0.3%, 0.4%, 0.5%, 0.6%, 0.7%, 0.8%, 0.9%, 1.0%, 1.1%, 1.2%, 1.3%, 1.4%, 1.5%, 1.6%, 1.7%, 1.8%, 1.9% or 2.0% by weight of the translucent layer, or in an amount up to half of said percentage amounts by weight of the whole material.

A ground cover material wherein the translucent layer, or layers, comprises a pigment (or pigments) in an amount not more than 20%, 15%, 10%, 5%, 4%, 2%, 1%, 0.5%,0.2% or 0.02% by weight of the translucent layer, or in an amount not more than 20%, 15%, 10%, 5%, 4%, 2%, 1%, 0.5%, 0.2% or 0.02% by weight of the whole material.

A ground cover material wherein the translucent layer, or layers, comprises at least one main white UV reflecting pigment, and at least one UV absorbing co-pigment.

A ground cover material wherein the UV absorbing pigment is an inorganic pigment.

A ground cover material wherein the UV absorbing co-pigment is an organic pigment.

A ground cover material wherein the low white layer, or layers, comprises at least one main white IR reflecting pigment.

A ground cover material wherein the low white layer, or layers, comprises at least one main white IR absorbing pigment.

A ground cover material wherein the white pigment is chosen from the group titanium, titanate, zirconium, silica, strontium, zinc, barium, potassium, calcium, magnesium and sodium.

A ground cover material wherein the white pigment is an oxide.

A ground cover material the coloured pigment is chosen from the group quinizarine, anthraquinone, diazo, anthracenedione, Solvaperm Black PCR, benzotriazole, benzophenone, triazine or oxalanilide.

A ground cover material wherein the coloured-translucent layer is translucent violet or indigo or blue or green or yellow or orange or red or grey, or black or white or a mixture of colours or shades of colours.

A ground cover material having a greater length than width and comprising:
on one side a low colour translucent layer comprising or composed of a transparent or translucent polymer and a low amount of coloured pigment (or pigments) or dye such that the translucent layer is coloured-translucent, and
on the other side a metallized layer.

A ground cover material the translucent layer comprises a pigment (or pigments) in an amount up to 0.001%, 0.1% or 0.2% or 0.3%, 0.4%, 0.5%, 0.6%, 0.7%, 0.8%, 0.9%, 1.0%, 1.1%, 1.2%, 1.3%, 1.4%, 1.5%, 1.6%, 1.7%, 1.8%, 1.9% or 2.0% by weight of the translucent layer, or in an amount up to half of said percentage amounts by weight of the whole material.

A ground cover material wherein the translucent layer comprises a pigment (or pigments) in an amount not more than 20%, 15%, 10%, 5%, 4%, 2%, 1%, 0.5%, 0.2%, 0.1% or 0.001% by weight of the translucent layer, or in an amount not more than 20%, 15%, 10%, 5%, 4%, 2%, 1%, 0.5%, 0.2%, 0.1% or 0.001% by weight of the whole material.

A ground cover material wherein the coloured pigment is chosen from the group quinizarine, anthraquinone, diazo, anthracenedione, fluorophores, fluorochromes, fluorescein, Rhodamine, Neocarmine, Solvaperm Black PCR, benzotriazole, benzophenone, triazine, oxalanilide or a combination of low-colour and white pigment.

A ground cover material wherein the coloured-translucent layer is translucent violet or indigo or blue or green or yellow or orange or red or grey, or black or white or a mixture of colours or shades of colours.

A ground cover material having a greater length than width and comprising:
on one side two or more translucent layers, each layer comprising or composed of a transparent or translucent polymer and a low amount of a white pigment (or pigments) and/or a low amount of coloured pigment or dye such that the translucent layers are white-translucent and/or coloured-translucent, and
on an opposite side a metallized layer.

A ground cover material the translucent layer comprises a pigment (or pigments) in an amount up to 0.01% or 0.1% or 0.2% or 0.3%, 0.4%, 0.5%, 0.6%, 0.7%, 0.8%, 0.9%, 1.0%, 1.1%, 1.2%, 1.3%, 1.4%, 1.5%, 1.6%, 1.7%, 1.8%, 1.9% or 2.0% by weight of the translucent layer, or in an amount up to half of said percentage amounts by weight of the whole material.

A ground cover material wherein the translucent layer comprises a pigment (or pigments) in an amount not more than 20%, 15%, 10%, 5%, 4%, 2%, 1%, 0.5%,0.2% or 0.02% by weight of the translucent layer, or in an amount not more than 20%, 15%, 10%, 5%, 4%, 2%, 1%, 0.5%, 0.2% or 0.002% by weight of the whole material.

A ground cover material wherein one or more of the translucent layers comprises at least one main white UV reflecting pigment, and at least one UV absorbing co-pigment.

A ground cover material wherein the UV absorbing pigment is an inorganic pigment.

A ground cover material wherein the UV absorbing co-pigment is an organic pigment.

A ground cover material wherein one or more of the translucent layers comprises at least one main IR reflecting pigment.

A ground cover material wherein one or more of the translucent layers comprises at least one main IR absorbing pigment.

A ground cover material wherein the white pigment is chosen from the group titanium, titanate, zirconium, silica, strontium, zinc, barium, potassium, calcium, magnesium and sodium.

A ground cover material wherein the white pigment is an oxide.

A ground cover material wherein the coloured pigment is chosen from the group quinizarine, anthraquinone, diazo, anthracenedione, Solvaperm Black PCR, benzotriazole, benzophenone, triazine or oxalanilide.

A ground cover material wherein the coloured-translucent layer is translucent violet or indigo or blue or green or yellow or orange or red or grey, or black or white or a mixture of colours or shades of colours.

A ground cover material wherein the metallized layer comprises an aluminium film.

A ground cover material wherein the metallized layer comprises antimony, silver or zinc.

A ground cover material wherein the ground cover material is a film between 1 and 50, 5 and 45, 10 and 40 or 14 and 35 microns thick.

A ground cover material in the form of a tape or film which is between 10 and 150, 10 and 100, 20 and 90, 30 and 80, 35 and 60, 35 and 55, or 40 and 60 microns thick.

A ground cover material wherein the low white-translucent or low coloured-translucent layer or layers diffuse at least 1%, 5%, 10%, 15%, 20%, 25%, 30%, 35%, 40%, 45%, 50%, 55%, 60%, 65%, 70%, 75%, 80%, 85%, 90% or 95% or more of direct light incident on the low white-translucent or low coloured-translucent layer or layers, and which is reflected back through it by the metal layer.

A ground cover material wherein the low white-translucent or low coloured-translucent layer or layers does not diffuse at least 5%, 10%, 20%, 30%, 40%, or 50% or more of direct light incident on the low white-translucent or low coloured-translucent layer or layers and which is reflected back through it by the metal layer.

A ground cover material wherein one or more of the low white-translucent or low coloured-translucent layer absorbs at least 1%, 2%, 3%, 4% 5%, 10%, 15%, 20%, 30%, 40% or 50% of light across a UV wavelength range of about 280 to about 420 nm.

A ground cover material wherein one or more of the low white-translucent or low coloured-translucent layer or layers diffuses at least 1%, 2%, 3%, 4% 5%, 10%, 15%, 20%, 30%, 40% or 50% of light across a UV wavelength range of about 280 to about 420 nm.

A ground cover material wherein the low white-translucent or low coloured-translucent layer:
absorbs and/or transmits more solar radiation than it diffusely reflects or diffuses in the UV range of about 280-400 nm, and
transmits at least part of solar radiation in the range about 800-2500 nm and at least part of solar radiation above about 2500 nm, and

A ground cover material wherein the low white-translucent or low coloured-translucent layer:
absorbs and/or transmits more solar radiation than it diffusely reflects or diffuses in the UV range of about 280-400 nm, and
transmits at least part of solar radiation in the range about 800-2500 nm and at least part of solar radiation above about 2500 nm, and
diffusely reflects at least 10% of solar radiation in the infrared range of about 1000-1500 nm, and
diffusely reflects at least about 20% of solar radiation in the infrared range of about 1500-2000 nm

A ground cover material wherein the low white-translucent or low coloured-translucent layer:
reflects and/or diffuses at least 20% in the UV range of about 280-400 nm, and reflects at least 30% in the visible range of about 400-700 nm and near infrared range of about 700-800 nm,
transmits and/or diffuses at least part of solar radiation in the range about 800-2500 nm and at least part of solar radiation above about 2500 nm, and
reflects and/or diffuses at least about 30% of solar radiation in the infrared range of about 700-1000 nm.

A ground cover material wherein the low white-translucent or low coloured-translucent layer:
absorbs or transmits more solar radiation than it reflects in the UV range of about 280-400 nm, and reflects at least 10% in the visible range of about 400-700 nm and near infrared range of about 700-800 nm,
transmits at least part of solar radiation in the range about 800-2500 nm and at least part of solar radiation above about 2500 nm, and
reflects at least about 10% of solar radiation in the infrared range of about 700-1000 nm.

A ground cover material wherein the low white-translucent or low coloured-translucent layer:
absorbs or transmits more solar radiation than it reflects and/or diffuses in the UV range of about 280-400 nm, and reflects at least 30% in the visible range of about 400-700 nm and near infrared range of about 700-800 nm,
transmits at least part of solar radiation in the range about 800-2500 nm and at least part of solar radiation above about 2500 nm, and
reflects and/or diffuses at least about 30% of solar radiation in the infrared range of about 700-1000 nm.

A ground cover material wherein the low white-translucent or low coloured-translucent layer reflects at least 1%, 2%, 3%, 4% 5%, 10%, 15%, 20%, 30%, 40% or 50% of visible light.

A ground cover material wherein the ground cover material that when placed low white-translucent or low coloured-translucent side up absorbs more light in the UV range of about 280-400 nm and light in the infrared range of about 700 -2500 nm than light in the visible range of about 421 -700 nm.

A ground cover material wherein the ground cover material that when placed low white-translucent or low coloured-translucent side up diffuses more light in the UV range of about 280-400 nm and light in the infrared range of about 700-2500 nm than light in the visible range of about 421-700 nm.

A ground cover material wherein the ground cover material that when placed low white-translucent or low coloured-translucent side up;
reflects diffuse and direct light in the UV range of about 280-400 nm, with at least 5% of reflected light being diffuse light, and
reflects diffuse and direct light in the visible range of about 421-700 nm, with at least 5% of reflected light being diffuse light

A ground cover material wherein the ground cover material that when placed low white-translucent or low coloured-translucent side up;
reflects diffuse and direct light in the UV range of about 280-400 nm, with at least 10% of reflected light being diffuse light, and
reflects diffuse and direct light in the visible range of about 421-700 nm, with at least 10% of reflected light being diffuse light

A ground cover material wherein the ground cover material that when placed low white-translucent or low coloured-translucent side up;
reflects diffuse and direct light in the UV range of about 280-400 nm, with at least 15% of reflected light being diffuse light, and
reflects diffuse and direct light in the visible range of about 421-700 nm, with at least 10% of reflected light being diffuse light.

A ground cover material wherein the ground cover material that when placed low white-translucent or low coloured-translucent side up reflects different proportions of diffuse light, and
reflects diffuse and direct light in the UV range of about 280-400 nm, with at least 50% of reflected light being diffuse light
reflects diffuse and direct light in the visible range of about 421-700 nm, with at least 30% of reflected light being diffuse light

A ground cover material wherein the ground cover material diffusely reflects at least 50% of reflected light across a UV wavelength range about 280 to about 420 nm and diffusely reflects less than about 80%, 70%, 60%, 50%, 40%, 30%, 20% or 10% of reflected light across a wavelength range of about 421 to about 700 nm,

A ground cover material wherein the ground cover material diffusely reflects at least 60% of reflected light across a UV wavelength range about 280 to about 420 nm and diffusely reflects less than about 50%, 40%, 30%, 20% or 10% of reflected light across a wavelength range of about 421 to about 700 nm,

A ground cover material wherein the ground cover material diffusely reflects at least 40% of reflected light across a UV wavelength range about 280 to about 420 nm and diffusely reflects less than 50%, 40%, 30%, 20% or 10% of reflected light across a wavelength range of about 421 to about 700 nm,

A ground cover sheet material wherein the ground cover material that when placed low-colour translucent side up, provides a portion of diffusely reflected light and a portion of directly reflected light:
reflects diffuse and direct light in the UV range of about 280-400 nm, with at least 5% of reflected light being diffuse light
reflects diffuse and direct light in the visible range of about 421-700 nm, with at least 5% of reflected light being diffuse light
absorbs and reflects diffuse and direct light in the UV and visible range of about 280-700 nm, with at least 5% of reflected light being diffuse light
reflects diffuse and direct light in the IR range of about 700-2500 nm, with at least 5% of reflected light being diffuse light

A method for generating diffuse light or reflected diffuse solar radiation and/or altering light energy and/or absorbing light from metallized film using a low white-translucent and/or low colour-translucent layer or layers.

A method for enhancing the growth or development of fruit comprising providing beneath fruit bearing plants a ground cover sheet material with the low white-translucent and/or low colour-translucent layer or layers uppermost.

A method of increasing the proportion of diffusely reflected light in the UV range of about 280-400 nm and diffusely reflected light in the infrared range of about 700-2500 nm to reduce heat intensity using the ground cover as claimed in any preceding claim.

A ground cover sheet material having a greater length than width and comprising:
one side comprising a light energy altering and/or diffusing and/or absorbing white or coloured layer or layers comprising or composed of a transparent or translucent polymer or polymers and a low amount of a white pigment and/or coloured pigment or pigments or coloured dye or coloured dyes such that the side is white-translucent or low coloured-translucent, and
the other side comprising a metallized layer.

A method for alternating light in a plant by the reflected solar radiation from a metalized film that is adjacent to a plant by adding light alternating chemistry to the base polymer layer that the metalized layer is bonded too such the base polymer layer is on the upper side and the metalized is on the lower side when placed in the field.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A ground cover material having a greater length than width and comprising:
a low white layer on a first side of the ground cover material, the low white layer being composed of a translucent polymer having a white pigment therein that causes the low white layer, to be white-translucent, and
a metallized layer on the opposite side of the ground cover material from the low white layer.

2. The ground cover material according to claim 1 wherein the low white layer includes a white pigment in an amount up between 0.1% to 2.0% by weight of the low white layer.

3. The ground cover material according to claim 1 wherein the low white layer includes a white pigment within the range of 0.1% to 20% by weight of the low white .

4. A ground cover material according to claim 1 wherein the low white layer comprises at least one main white UV reflecting pigment and at least one UV absorbing pigment.

5. A ground cover material according to claim 4 wherein the UV absorbing pigment is an inorganic pigment.

6. (canceled)

7. A ground cover material according to claim 1 wherein the low white layer comprises at least one main white IR reflecting pigment.

8. A ground cover material according to claim 1 wherein the low white layer comprises at least one main white IR absorbing pigment.

9-20. (canceled)

21. The ground cover material according to claim 1 wherein the coloured pigment is chosen from a compound within the group of: quinizarine, anthraquinone, diazo, anthracenedione, Solvaperm Black PCR, benzotriazole, benzophenone, triazine or oxalanilide.

22-27. (canceled)

28. A ground cover material having a greater length than width and comprising:
two or more translucent layers on a first side, each layer composed of a translucent polymer and a low amount of a white pigment and a low amount of coloured pigment such that the translucent layers are white-translucent and coloured-translucent, and
a metallized layer on a second side thereof.

29-30. (canceled)

31. The ground cover material according to claim 28 wherein one or more of the translucent layers comprises at least one main white UV reflecting pigment, and at least one UV absorbing co-pigment.

32. The ground cover material according to claim 31 wherein the UV absorbing pigment is an inorganic pigment.

33. The ground cover material according to claim 31 wherein the UV absorbing co-pigment is an organic pigment.

34. The ground cover material according to claim 28 wherein one or more of the translucent layers comprises at least one main IR reflecting pigment.

35. The ground cover material according to claim 28 31 wherein one or more of the translucent layers comprises at least one main IR absorbing pigment.

36-39. (canceled)

40. The ground cover material according to claim 28 wherein the metallized layer comprises an aluminum film.

41. The ground cover material according to claim 28 wherein the metallized layer comprises antimony, silver or zinc.

42-47. (canceled)

48. A ground cover material according to claim 28 wherein the low white-translucent or low coloured-translucent layer:
absorbs and/or transmits more solar radiation than it diffusely reflects or diffuses in the UV range of about 280-400 nm, and
transmits at least part of solar radiation in the range about 800-2500 nm and at least part of solar radiation above about 2500 nm, and.

49. A ground cover material according to claim 28 wherein the low white-translucent or low coloured-translucent layer:
• absorbs and/or transmits more solar radiation than it diffusely reflects or diffuses in the UV range of about 280-400 nm, and
• transmits at least part of solar radiation in the range about 800-2500 nm and at least part of solar radiation above about 2500 nm, and
• diffusely reflects at least 10% of solar radiation in the infrared range of about 1000-1500 nm, and
• diffusely reflects at least about 20% of solar radiation in the infrared range of about 1500-2000 nm.

50. A ground cover material according to claim 28 wherein the low white-translucent or low coloured-translucent layer:
• reflects and/or diffuses at least 20% in the UV range of about 280-400 nm, and reflects at least 30% in the visible range of about 400-700 nm and near infrared range of about 700-800 nm,
• transmits and/or diffuses at least part of solar radiation in the range about 800-2500 nm and at least part of solar radiation above about 2500 nm, and
• reflects and/or diffuses at least about 30% of solar radiation in the infrared range of about 700-1000 nm.

51-63. (canceled)

64. A method for generating diffuse light to a living plant comprising:
placing a ground cover material on the ground adjunct to the plant, the ground cover material including a layer having metal therein proximate to the ground, a layer having a low white-translucent material further from the ground than the metal layer and a layer of low colored-translucent further from the ground than the metal layer.
reflecting diffuse and direct light in the UV range of about 280-400 nm, with at least 50% of reflected light being diffuse light; and
reflects diffuse and direct light in the visible range of about 421-700 nm, with at least 30% of reflected light being diffuse light.

65-68. (canceled)
